(19) United States
(12) Patent Application Publication
(10) Pub. No.: US 2026/0253544 A1
(43) Pub. Date: Aug. 27, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventor: EOK SU KIM, Yongin-si (KR)

(21) Appl. No.: 19/381,110

(22) Filed: Nov. 6, 2025

(30) Foreign Application Priority Data
Feb. 21, 2025 (KR) 10-2025-0023029

(51) Int. Cl. G09G 3/3233

(52) U.S. Cl. CPC G09G 3/3233; G09G 2300/0819; G09G 2300/0852; G09G 2300/0861; G09G 2310/0286; G09G 2320/0257; G09G 2320/06; G09G 2340/0435

(57) ABSTRACT

A display device includes a first sub-pixel, a second sub-pixel spaced apart from the first sub-pixel in a first direction and emitting light of substantially the same color as the first sub-pixel, a first scan line extending in the first direction, electrically connected to the first sub-pixel, and transmitting a first scan signal to the first sub-pixel, a second scan line extending in the first direction, electrically connected to the second sub-pixel, and transmitting a second scan signal to the second sub-pixel, and a data line extending in a second direction intersecting the first direction and electrically connected to the first sub-pixel and the second sub-pixel.

### CROSS-REFERENCE TO RELATED APPLICATIONS

This application claims priority under 35 U.S.C. § 119 to and benefits from Korean Patent Application No. 10-2025-0023029 filed on February 21, 2025 in the Korean Intellectual Property Office (KIPO), the entire disclosure of which is incorporated by reference.

### TECHNICAL FIELD

The disclosure generally relates to a display device improved in image quality and an electronic device including the same.

### DISCUSSION OF RELATED ART

Multimedia electronic devices, such as a television, a cellular phone, a tablet computer, a navigation system, and a game console, include a display device that displays an image. The display device includes a display panel and a driver. The driver includes a scan driving circuit to provide a scan signal to multiple scan lines and a data driving circuit to provide a data voltage to multiple data lines.

### SUMMARY

Embodiments of the disclosure provide a display device improved in image quality and an electronic device including the same.

According to an embodiment of the disclosure, a display device may include a first sub-pixel, a second sub-pixel spaced apart from the first sub-pixel in a first direction and emitting light of substantially the same color as the first sub-pixel, a first scan line extending in the first direction, electrically connected to the first sub-pixel, and transmitting a first scan signal to the first sub-pixel, a second scan line extending in the first direction, electrically connected to the second sub-pixel, and transmitting a second scan signal to the second sub-pixel, and a data line extending in a second direction intersecting the first direction and electrically connected to the first sub-pixel and the second sub-pixel.

According to an embodiment of the disclosure, the first sub-pixel and the second sub-pixel may be driven in multiple operating modes, and the operating modes may include a first mode and a second mode having mutually different frame rates.

According to an embodiment of the disclosure, a first activation time point of the first scan signal may differ from a second activation time point of the second scan signal, in the first mode.

According to an embodiment of the disclosure, a first activation time point of the first scan signal may be the same as a second activation time point of the second scan signal, in the second mode.

According to an embodiment of the disclosure, a second frame rate in the second mode may be two times a first frame rate in the first mode.

According to an embodiment of the disclosure, each of the first sub-pixel and the second sub-pixel may include a first transistor, a second transistor, and a third transistor, the second transistor of the first sub-pixel and the third transistor of the first sub-pixel may be controlled in operation by the first scan signal, and the second transistor of the second sub-pixel and the third transistor of the second sub-pixel may be controlled in operation by the second scan signal

According to an embodiment of the disclosure, the display device may further include a third sub-pixel spaced apart from the first sub-pixel in the second direction intersecting the first direction, a fourth sub-pixel spaced apart from the third sub-pixel in the first direction, a third scan line extending in the first direction, electrically connected to the third sub-pixel, and transmitting a third scan signal to the third sub-pixel, and a fourth scan line extending in the first direction, electrically connected to the fourth sub-pixel, and transmitting a fourth scan signal to the fourth sub-pixel. The first sub-pixel, the second sub-pixel, the third sub-pixel, and the fourth sub-pixel may emit light of substantially the same color.

According to an embodiment of the disclosure, the first sub-pixel, the second sub-pixel, the third sub-pixel, and the fourth sub-pixel may be driven in multiple operating modes, and the operating modes may include a first mode, a second mode, and a third mode having mutually different frame rates.

According to an embodiment of the disclosure, a first activation time point of the first scan signal, a second activation time point of the second scan signal, a third activation time point of the third scan signal, and a fourth activation time point of the fourth scan signal may differ from each other, in the first mode.

According to an embodiment of the disclosure, the first activation time point of the first scan signal may be the same as the second activation time point of the second scan signal, the third activation time point of the third scan signal may be the same as the fourth activation time point of the fourth scan signal, and the first activation time point may differ from the third activation time point, in the second mode.

According to an embodiment of the disclosure, the first activation time point of the first scan signal, the second activation time point of the second scan signal, the third activation time point of the third scan signal, and the fourth activation time point of the fourth scan signal may be the same, in the third mode.

According to an embodiment of the disclosure, a second frame rate in the second mode may be two times a first frame rate in the first mode, and a third frame rate in the third mode may be four times the first frame rate in the first mode.

According to an embodiment of the disclosure, a first horizontal resolution in the first direction may be symmetrical to a first vertical resolution in the second direction, in the first mode, and a second horizontal resolution in the first direction is symmetrical to a second vertical resolution in the second direction, in the third mode.

According to an embodiment of the disclosure, each of the first sub-pixel, the second sub-pixel, the third sub-pixel, and the fourth sub-pixel may include a first transistor, a second transistor, and a third transistor, the second transistor of the first sub-pixel and the third transistor of the first sub-pixel may be controlled in operation by the first scan signal, the second transistor of the second sub-pixel and the third transistor of the second sub-pixel may be controlled in operation by the second scan signal, the second transistor of the third sub-pixel and the third transistor of the third sub-pixel may be controlled in operation by the third scan signal, and the second transistor of the fourth sub-pixel and the third transistor of the fourth sub-pixel may be controlled in operation by the fourth scan signal.

According to an embodiment of the disclosure, a display device may include a first pixel group including a first sub-pixel, a second pixel group spaced apart from the first pixel group in a first direction and including a second sub-pixel, a third pixel group spaced apart from the first pixel group in a second direction intersecting the first direction and including a third sub-pixel, a fourth pixel group spaced apart from the third pixel group in the first direction and including a fourth sub-pixel, a data line extending in the second direction, and electrically connected to the first sub-pixel, the second sub-pixel, the third sub-pixel, and the fourth sub-pixel, a first scan line extending in the first direction, electrically connected to the first sub-pixel, and transmitting a first scan signal to the first sub-pixel, a second scan line extending in the first direction, electrically connected to the second sub-pixel, and transmitting a second scan signal to the second sub-pixel, a third scan line extending in the first direction, electrically connected to the third sub-pixel, and transmitting a third scan signal to the third sub-pixel, and a fourth scan line extending in the first direction, electrically connected to the fourth sub-pixel, and transmitting a fourth scan signal to the fourth sub-pixel. The first sub-pixel, the second sub-pixel, the third sub-pixel, and the fourth sub-pixel may emit light of substantially the same color.

According to an embodiment of the disclosure, the first sub-pixel, the second sub-pixel, the third sub-pixel, and the fourth sub-pixel may be driven in multiple operating modes, and the plurality of operating modes may include a first mode, a second mode, and a third mode.

According to an embodiment of the disclosure, a first activation time point of the first scan signal, a second activation time point of the second scan signal, a third activation time point of the third scan signal, and a fourth activation time point of the fourth scan signal may differ from each other, in the first mode. The first activation time point may be the same as the second activation time point, the third activation time point may be the same as the fourth activation time point, and the first activation time point differs from the third activation time point, in the second mode. The first activation time point, the second activation time point, the third activation time point, and the fourth activation time point may be the same, in the third mode.

According to an embodiment of the disclosure, a second frame rate in the second mode may be two times a first frame rate in the first mode, and a third frame rate in the third mode may be four times the first frame rate in the first mode.

According to an embodiment of the disclosure, a first horizontal resolution in the first direction may be symmetrical to a first vertical resolution in the second direction, in the first mode, and a second horizontal resolution in the first direction is symmetrical to a second vertical resolution in the second direction, in the third mode.

According to an embodiment of the disclosure, an electronic device may include a display device and a processor to control the operation of the display device. The display device may include a display panel including a plurality of sub-pixels arranged in a first direction and a second direction intersecting the first direction, a plurality of scan lines electrically connected to the plurality of sub-pixels, and a plurality of data lines electrically connected to the plurality of sub-pixels, and a data driving circuit to output a plurality of data signals to the plurality of data lines. The plurality of sub-pixels may include a first sub-pixel, a second sub-pixel spaced apart from the first sub-pixel in the first direction, a third sub-pixel spaced apart from the first sub-pixel in the second direction, and a fourth sub-pixel spaced apart from the third sub-pixel in the first direction. The plurality of scan lines may include a first scan line electrically connected to the first sub-pixel, a second scan line electrically connected to the second sub-pixel, a third scan line electrically connected to the third sub-pixel, and a fourth scan line electrically connected to the fourth sub-pixel. The plurality of data lines may include one data line electrically connected to all of the first sub-pixel, the second sub-pixel, the third sub-pixel, and the fourth sub-pixel. The first sub-pixel, the second sub-pixel, the third sub-pixel, and the fourth sub-pixel may emit light of substantially the same color.

### BRIEF DESCRIPTION OF THE DRAWINGS

The above and other objects and features of the disclosure will become apparent by describing in detail embodiments thereof with reference to the accompanying drawings.

FIG. 1 is a block diagram of an electronic device according to an embodiment of the disclosure;

FIG. 2 illustrates schematic views of an electronic device according to various embodiments of the disclosure;

FIG. 3 is a block diagram illustrating an electronic device according to an embodiment of the disclosure;

FIG. 4 is a view illustrating four pixel groups according to an embodiment of the disclosure;

FIG. 5A is an example schematic diagram of an equivalent circuit of a first sub-pixel according to an embodiment of the disclosure;

FIG. 5B is an example schematic diagram of an equivalent circuit of a first sub-pixel according to an embodiment of the disclosure;

FIG. 6 is a view to describe a scan driving circuit according to an embodiment of the disclosure;

FIG. 7 is an example schematic diagram of an equivalent circuit of a first sub-pixel to a fourth sub-pixel according to an embodiment of the disclosure;

FIG. 8A is a view to describe a first mode according to an embodiment of the disclosure;

FIG. 8B is a view to describe a first image displayed in a first mode according to an embodiment of the disclosure;

FIG. 9A is a view to describe a second mode according to an embodiment of the disclosure;

FIG. 9B is a view to describe a second image displayed in a second mode according to an embodiment of the disclosure;

FIG. 10A is a view to describe a third mode according to an embodiment of the disclosure; and

FIG. 10B is a view to describe a third image displayed in a third mode according to an embodiment of the disclosure.

### DETAILED DESCRIPTION

In the specification, the expression that a first component (or region, layer, or part) is “on”, “connected to”, or “coupled to” a second component refers to that the first component is directly on, connected to, or coupled to the second component or refers to that a third component is disposed therebetween.

The same reference numeral will be assigned to the same component. In drawings, thicknesses, proportions, and dimensions of components may be exaggerated to describe the technical features effectively. The term “and/or” includes any and all combinations of one or more of associated components.

Although the terms “first”, or “second” may be used to describe various components, the components should not be construed as being limited by the terms. The terms are used to distinguish one component from another component. For example, without departing from the scope and spirit of the disclosure, a first component may be referred to as a second component, and similarly, the second component may be referred to as the first component. The singular forms are intended to include the plural forms unless the context clearly indicates otherwise.

The terms “under”, “at a lower portion”, “above”, “an upper portion” are used to describe the relationship between components illustrated in drawings. The terms are relative and will be described with reference to a direction indicated in the drawing.

It will be further understood that the terms “comprise,” “include,” or “including,” or “have” or “having” specify the presence of stated features, numbers, steps, operations, components, parts, or the combination thereof, but do not preclude the presence or addition of one or more other features, numbers, steps, operations, components, components, and/or the combination thereof.

The terms “part” and “unit” refer to a software component or a hardware component to perform a specific function. The hardware component may include field-programmable gate array (FPGA) or an application-specific integrated circuit (ASIC). The software component may refer to an executable code and/or data used by the executable code in an addressable storage medium. Accordingly, software components may be, for example, object-oriented software components, class components, and task components, and may include processes, functions, properties, procedures, subroutines, program code segments, driver data, firmware, microcodes, circuits, data, database, data structures, tables, arrangements or variables.

Unless defined otherwise, all terms (including technical terms and scientific terms) used in the specification have the same meaning as commonly understood by one skilled in the art to which the disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Embodiments of the disclosure pertain to a display device and an electronic device that seeks to limit motion blur. Several operational modes are disclosed, one being where the sub-pixels of a same color are driven individually, and two modes where the sub-pixels are driven simultaneously. In either case, each of the sub-pixels are connected to a same data line but are connected to different scan lines so that they can be driven either individually or simultaneously. In the former case, the horizontal and vertical resolution are symmetrical, so that the user does not perceive motion blur. In the latter cases, the frame rate is increased, so that motion blur is not perceived as the horizontal and vertical resolutions are symmetrical.

Hereinafter, embodiments of the disclosure will be described with reference to accompanying drawings.

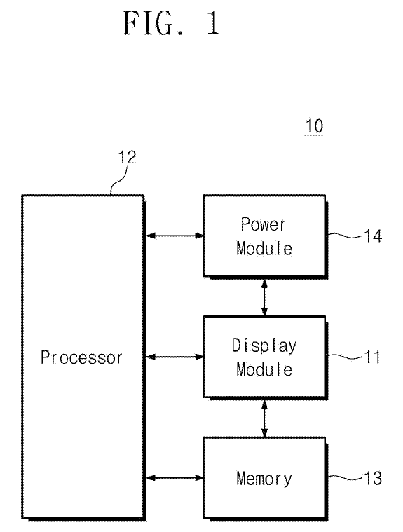

FIG. 1 is a block diagram of an electronic device 10 according to an embodiment of the disclosure.

Referring to FIG. 1, the electronic device 10 according to an embodiment may include a display module 11, a processor 12, a memory 13, and a power module 14.

The display module 11 may display image. The image may include a still image as well as a video (or a moving image). The processor 12 may include at least one of a central processing unit (CPU), an application processor (AP), a graphic processing unit (GPU), a communication processor (CP), an image signal processor (ISP), or a controller. The processor 12 may be configured to control the operation of the display module 11.

The memory 13 may store data information necessary for the operation of the processor 12 or the display module 11. In case that the processor 12 runs the application stored in the memory 13, an image data signal and/or an input control signal may be transmitted to the display module 11, and the display module 11 may process the transmitted signal and output the image information through the display screen.

The power module 14 may include a power supply module, such as a power adaptor or a battery device, and a power converting module to convert the power supplied from the power supply module into power necessary for the operation of the electronic device 10.

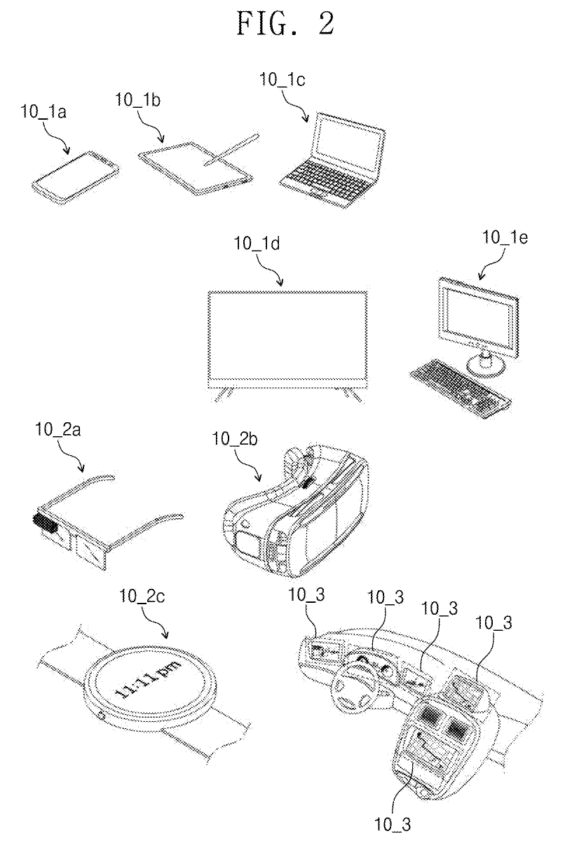

FIG. 2 illustrates schematic views of an electronic device according to various embodiments of the disclosure.

Referring to FIG. 2, various electronic devices employing the display device according to embodiments may include a wearable electronic device including a display module such as smart glasses 10_2a, a head mounted display 10_2b, and a smart watch 10_2c, and an electronic device 10-3 for the vehicle including the display module such as a center information display (CID) which is disposed in an instrument panel, a center fascia, and a dashboard of a vehicle, or a room mirror display, as well as an electronic device for image display such as a smartphone 10_1a, a tablet 10_1b, a laptop computer 10_1c, a television (TV) 10_1d, and a computer monitor 10_1e.

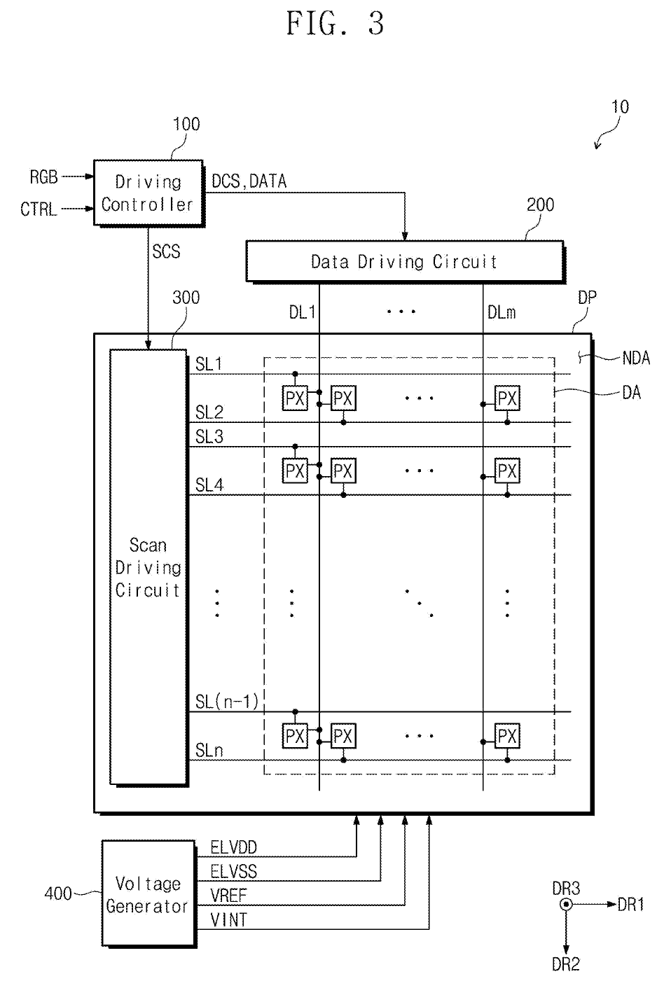

FIG. 3 is a block diagram illustrating the electronic device 10 according to an embodiment of the disclosure.

Referring to FIG. 3, the electronic device 10 may include a display device. The display device may include a driving controller 100, a data driving circuit 200, a voltage generator 400, and a display panel DP. The processor 12 described with reference to FIG. 1 may control the operation of the display device. The display panel DP may correspond to the display module 11 described with reference to FIG. 1.

The driving controller 100 may receive an input image signal RGB and a control signal CTRL. The driving controller 100 may generate an output image signal DATA by converting a data format of the input image signal RGB in compliance with the specification for an interface with the data driving circuit 200. The driving controller 100 may output a data control signal DCS and a scan control signal SCS.

The data driving circuit 200 may receive the data control signal DCS and the output image signal DATA from the driving controller 100. The data driving circuit 200 may convert the output image signal DATA into data signals and may output the data signals to a plurality data lines DL1 to DLm to be described. Each of the data signals may have a voltage level corresponding to a grayscale level of the output image signal DATA.

The data driving circuit 200 may be implemented in the form of an integrated circuit (IC), and mounted (e.g., directly mounted) in a specific region of the display panel DP or mounted in the form of a chip on film (COF) manner on a separate printed circuit board, such that the data driving circuit 200 is electrically connected to the display panel DP. According to an embodiment, the driving controller 100 and the data driving circuit 200 may be implemented in the form of individual chips separated from each other, or may be single, uninterrupted chip. According to an embodiment, the data driving circuit 200 may be formed on the display panel DP through a process the same as a process for a pixel circuit in each of pixel groups PX.

The voltage generator 400 may generate voltages necessary for the operation of the display panel DP. According to the embodiment, the voltage generator 400 may generate a first driving voltage ELVDD, a second driving voltage ELVSS, a reference voltage VREF, and an initializing voltage VINT.

The display panel DP may include a display region DA and a non-display region NDA. According to an embodiment, the display region DA may have a rectangular shape, but the disclosure is not necessarily limited thereto. The non-display region NDA may have the shape of a frame surrounding the display region DA.

The display panel DP may further include a scan driving circuit 300. The pixel groups PX may be disposed in the display region DA, and the scan driving circuit 300 may be disposed in the non-display region NDA. However, the disclosure is not necessarily limited thereto. At least some of the pixel groups PX may overlap the scan driving circuit 300. At least a portion of the scan driving circuit 300 may be disposed in the display region DA.

The display panel DP may include multiple scan lines SL1 to SLn, the data lines DL1 to DLm, and the pixel groups PX. Herein, “n” may be an integer of at least ‘2’ and “m” may be an integer of at least ‘2’.

The scan driving circuit 300 may receive the scan control signal SCS from the driving controller 100. The scan driving circuit 300 may output scan signals to the scan lines SL1 to SLn in response to the scan control signal SCS.

The scan driving circuit 300 may be disposed at a first side of the display layer DP. The scan lines SL1 to SLn may extend in a first direction DR1 from the scan driving circuit 300. The scan lines SL1 to SLn may be spaced apart from each other in a second direction DR2. The data lines DL1 to DLm extend in the second direction DR2 from the data driving circuit 200 and may be spaced apart from each other in the first direction DR1.

The pixel groups PX may be arranged in the first direction DR1 and the second direction DR2. Each of the pixel groups PX may include multiple sub-pixels, and a pixel group PX may be connected to the data lines. For example, in case that one (e.g., a single) pixel group PX includes a red sub-pixel, a green sub-pixel, and a blue sub-pixel, one (e.g., a single) pixel group PX may be connected to three data lines. FIG. 3 representatively illustrates a data line connected to a sub-pixel among the three data lines.

According to an embodiment of the disclosure, each of the sub-pixels included in each of the pixel groups PX may be electrically connected to a scan line and a data line. Sub-pixels emitting light having the same color in the pixel groups PX which are arranged in two columns adjacent to each other among the pixel groups PX may be electrically connected to the same data line. The pixel groups PX which are arranged in two columns adjacent to each other may be pixel groups PX arranged in a k-th column and pixel groups PX arranged in a (k+1)-th column where ‘k’ may be an odd number. For example, a first sub-pixel of the pixel groups PX arranged in a first column and a second sub-pixel of the pixel groups PX arranged in a second column are electrically connected to the first data line DL1 and may share the first data line DL1.

According to an embodiment of the disclosure, among pixel groups PG arranged in the same row, some pixel groups PG and remaining pixels groups PG may be connected to mutually different scan lines. For example, the pixel groups PX arranged in the same row and odd-numbered columns may be electrically connected to one (e.g., a single) scan line. Pixel groups PX which are arranged in even-numbered columns among the pixel groups PX in the same row may be electrically connected to another scan line.

For example, the pixel group PX which is arranged in a first column among the pixel groups PX arranged in a first row may be electrically connected to the first scan line SL1 and the first data line DL1, and the pixel group PX which is arranged in the second column among the pixel groups PX arranged in the first row may be electrically connected to the second scan line SL2 and the first data line DL1.

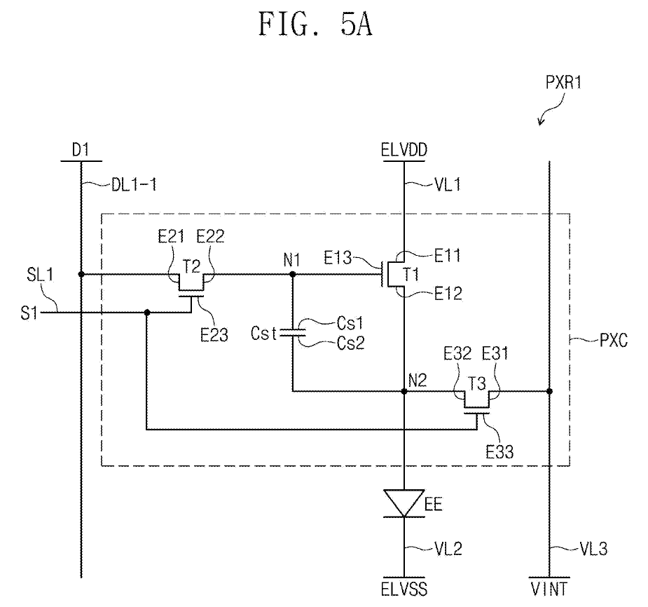

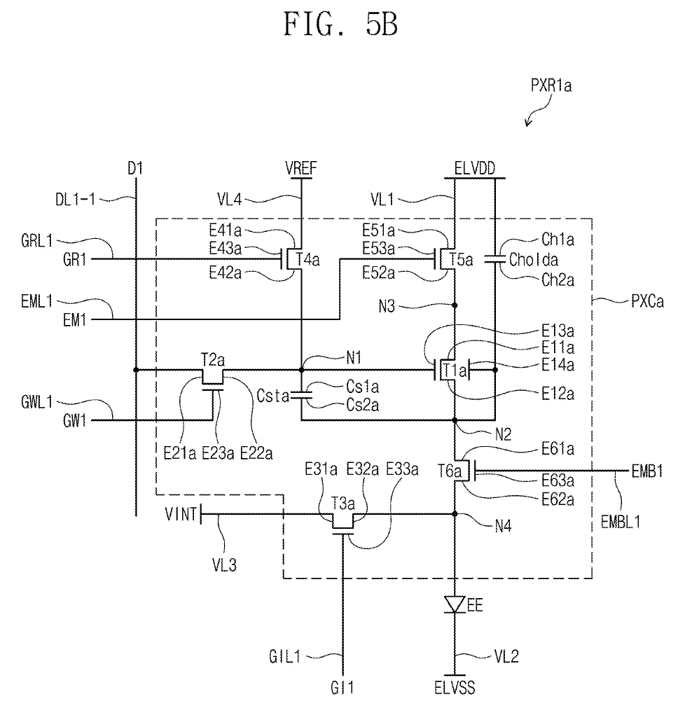

Each of the sub-pixels includes a light emitting element EE (see FIG. 5A) and a pixel circuit PXC (see FIG. 5A) controlling the light emission of the light emitting element EE. The pixel circuit PXC may include at least one transistor and at least one capacitor. Transistors of the scan driving circuit 300 and the pixel circuit PXC may be formed through a same process.

Each of the pixel groups PX may receive the first driving voltage ELVDD, the second driving voltage ELVSS, the reference voltage VREF, and the initializing voltage VINT from the voltage generator 400.

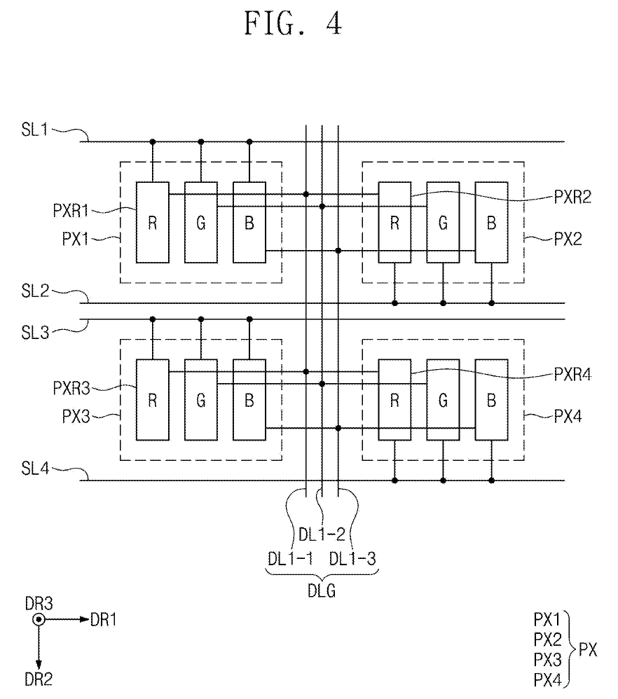

FIG. 4 is a view illustrating four pixel groups PX according to an embodiment of the disclosure.

FIG. 4 illustrates pixel groups PX1, PX2, PX3, and PX4 electrically connected to one (e.g., single) data line group DLG, the first scan line SL1, the second scan line SL2, the third scan line SL3, and the fourth scan line SL4.

Referring to FIGS. 3 and 4, the display panel DP may include the pixel groups PX. Hereinafter, a pixel group PX1 electrically connected to the first scan line SL1 may be referred to as a first pixel group PX1, a pixel group PX2 electrically connected to the second scan line SL2 may be referred to as a second pixel group PX2, a pixel group PX3 electrically connected to the third scan line SL3 may be referred to as a third pixel group PX3, and the pixel group PX4 electrically connected to the fourth scan line SL4 may be referred to as a fourth pixel group PX4.

The first to fourth pixel groups PX1, PX2, PX3, and PX4 may be arranged in the first direction DR1 and the second direction DR2. The second pixel group PX2 may be spaced apart from the first pixel group PX1 in the first direction DR1, the third pixel group PX3 may be spaced apart from the first pixel group PX1 in the second direction DR2, and the fourth pixel group PX4 may be spaced apart from the third pixel group PX3 in the first direction DR1.

According to an embodiment of the disclosure, each of the first to fourth pixel groups PX1, PX2, PX3, and PX4 may include multiple sub-pixels R, G, and B. Although FIG. 4 illustrates that each of the first to fourth pixel groups PX1, PX2, PX3, and PX4 includes the red sub-pixel R, the green sub-pixel G, and the blue sub-pixel B, the disclosure is not particularly limited thereto. For example, each of the first to fourth pixel groups PX1, PX2, PX3, and PX4 may further include at least one of a white sub-pixel, a magenta sub-pixel, or a cyan sub-pixel, or may include multiple green sub-pixels. In other words, the combination of sub-pixels constituting each of the first to fourth pixel groups PX1, PX2, PX3, and PX4 may be variously modified.

According to an embodiment of the disclosure, a data line group DLG may include multiple data lines DL1-1, DL1-2, and DL1-3. The data lines DL1-1, DL1-2, and DL1-3 may include the first data line DL1-1, the second data line DL1-2, and the third data line DL1-3. Each of the first data line DL1-1, the second data line DL1-2, and the third data line DL1-3 may be electrically connected to sub-pixels which emit light having the same color in the first to fourth pixel groups PX1, PX2, PX3, and PX4. For example, the first data line DL1-1 may be electrically connected to the red sub-pixels R in the first to fourth pixel groups PX1, PX2, PX3, and PX4, the second data line DL1-2 may be electrically connected to the green sub-pixels G in the first to fourth pixel groups PX1, PX2, PX3, and PX4, and the third data line DL1-3 may be electrically connected to the blue sub-pixels B in the first to fourth pixel groups PX1, PX2, PX3, and PX4.

Hereinafter, the red sub-pixels R in the first to fourth pixel groups PX1, PX2, PX3, and PX4 are referred to as the first to fourth sub-pixels PXR1, PXR2, PXR3, and PXR4, respectively, and the description about the first to fourth sub-pixels PXR1, PXR2, PXR3, and PXR4 may be identically applied to the green sub-pixels G and the blue sub-pixels B. One of the first to third data lines DL1-1, DL1-2, and DL1-3 illustrated in FIG. 4 may correspond to the first data line DL1 illustrated in FIG. 3.

According to an embodiment of the disclosure, the first pixel group PX1 may include the first sub-pixel PXR1, the second pixel group PX2 may include the second sub-pixel PXR2, the third pixel group PX3 may include the third sub-pixel PXR3, and the fourth pixel group PX4 may include the fourth sub-pixel PXR4.

According to an embodiment of the disclosure, the first sub-pixel PXR1 may be electrically connected to the first scan line SL1, the second sub-pixel PXR2 may be electrically connected to the second scan line SL2, the third sub-pixel PXR3 may be electrically connected to the third scan line SL3, and the fourth sub-pixel PXR4 may be electrically connected to the fourth scan line SL4. All of the first to fourth sub-pixels PXR1, PXR2, PXR3, and PXR4 may be electrically connected to one (e.g., a single) first data line DL1-1.

According to an embodiment of the disclosure, the first to fourth sub-pixels PXR1, PXR2, PXR3, and PXR4 may emit light having substantially the same color. For example, the first to fourth sub-pixels PXR1, PXR2, PXR3, and PXR4 may all emit red light.

FIG. 5A is an example schematic diagram of an equivalent circuit of the first sub-pixel according to an embodiment of the disclosure.

Referring to FIGS. 3, 4, and 5A, the example schematic diagram of an equivalent circuit of the first sub-pixel PXR1 connected to the first data line DL1-1 and the first scan line SL1 is illustrated.

The first sub-pixel PXR1 may include the pixel circuit PXC and the light emitting element EE. The pixel circuit PXC may include first to third transistors T1, T2, and T3 and a capacitor Cst. The first sub-pixel PXR1 illustrated in FIG. 5A is provided for the illustrative purpose, and the circuit diagram of the first sub-pixel PXR1 may be modified for implementation.

Each of the first to third transistors T1 to T3 may be an N-type transistor having an oxide semiconductor layer. The first transistor T1 may also be referred to as a driving transistor, the second transistor T2 may be referred to as a switching transistor, and the third transistor T3 may also referred to as an initializing transistor.

The first scan line SL1 may transmit the first scan signal S1 to the first sub-pixel PXR1. The first data line DL1-1 may transmit the data signal D1 to the first sub-pixel PXR1. The data signal D1 may have a voltage level corresponding to the image signal RGB input to the electronic device 10.

First to third driving voltage lines VL1, VL2, and VL3 may transmit the first driving voltage ELVDD, the second driving voltage ELVSS, and the initializing voltage VINT to the first sub-pixel PXR1, respectively.

The first transistor T1 may include a first electrode E11 electrically connected to the first driving voltage line VL1, a second electrode E12 electrically connected to an anode of the light emitting element EE, and a gate electrode E13. A connection part between the second electrode E12 of the first transistor T1 and the light emitting element EE may be defined as a second node N2.

The second transistor T2 may include a first electrode E21 connected to the first data line DL1-1, a second electrode E22 connected to the first node N1, and a gate electrode E23 connected to the first scan line SL1. The second transistor T2 may transmit the data signal D1 which is received through the first data line DL1-1 to the first node N1, in response to the first scan signal SL1 received through the first scan line SL1.

The third transistor T3 may include a first electrode E31 connected to the third driving voltage line VL3, a second electrode E32 connected to the second node N2, and a gate electrode E33 connected to the first scan line SL1. The third transistor T3 may transmit the initializing voltage VINT which is received through the third driving voltage line VL3 to the second node N2 in response to the first scan signal S1 received through the first scan line SL1.

Although FIG. 5A illustrates that the second transistor T2 and the third transistor T3 are controlled in operation by the same scan signal SL1, the disclosure is not necessarily limited thereto. For example, the second transistor T2 and the third transistor T3 may be controlled in operation by mutually different scan signals.

The capacitor Cst may be connected between the first node N1 and the second node N2. A first opposite electrode Cs1 of the capacitor Cst may be connected to the first node N1, and a second opposite electrode Cs2 of the capacitor Cst may be connected to the second node N2.

The light emitting element EE may include the anode connected to the second node N2 and a cathode connected to the second driving voltage line VL2. The light emitting element EE may be an organic light emitting diode including an organic light emitting layer, but the disclosure is not necessarily limited thereto.

Although FIG. 5A illustrates an example schematic diagram of an equivalent circuit of the first sub-pixel PXR1, equivalent circuits of the second sub-pixel PXR2, the third sub-pixel PXR3, and the fourth sub-pixel PXR4 illustrated in FIG. 4 may have configurations the same as the configuration of the equivalent circuit of the first sub-pixel PXR1.

FIG. 5B is an example schematic diagram of an equivalent circuit of a first sub-pixel PXR1a according to an embodiment of the disclosure.

Referring to FIGS. 3, 4, and 5B, an example schematic diagram of an equivalent circuit of the first sub-pixel PXR1a connected to the first data line DL1-1, scan lines GIL1, GRL1, and GWL1, and emission control lines EML1 and EMBL1 is illustrated.

The first sub-pixel PXR1a may include the pixel circuit PXCa and the light emitting element EE. The pixel circuit PXCa may include first to sixth transistors T1a, T2a, T3a, T4a, T5a and T6a, a first capacitor Csta, and a second capacitor Cholda. The first capacitor Csta and the second capacitor Cholda may be referred to as a transfer capacitor Csta and a hold capacitor Cholda, respectively. The first sub-pixel PXR1a illustrated in FIG. 5B is provided for the illustrative purpose, and the circuit diagram of the first sub-pixel PXR1a may be modified for implementation.

Each of the first to sixth transistors T1a, T2a, T3a, T4a, T5a, and T6a may be an N-type transistor having an oxide semiconductor layer. The first transistor T1a may also be referred to as a driving transistor, the second transistor T2a may be referred to as a switching transistor, the third transistor T3a may be referred to as an initializing transistor, the fourth transistor T4a may be referred to as a compensating transistor, the fifth transistor T5a may be referred to as a first emission control transistor, and the sixth transistor T6a may also be referred to as a second emission control transistor.

The scan lines GIL1, GRL1, and GWL1 may transmit scan signals GI1, GR1, and GW1 to the first sub-pixel PXR1a, and the emission control lines EML1 and EMBL1 may transmit emission signals EM1 and EMB1 to the first sub-pixel PXR1a, respectively. The first data line DL1-1 may transmit the data signal D1 to the first sub-pixel PXR1a. The data signal D1 may have a voltage level corresponding to the image signal RGB input to the electronic device 10.

The first to fourth driving voltage lines VL1, VL2, VL3, and VL4 may transmit the first driving voltage ELVDD, the second driving voltage ELVSS, and the initializing voltage VINT, and the reference voltage VREF to the first sub-pixel PXR1a, respectively.

The first capacitor Csta may be connected between the first node N1 and the second node N2. The first opposite electrode Cs1a of the first capacitor Csta may be connected to the first node N1, and the second opposite electrode Cs2a of the first capacitor Csta may be connected to the second node N2.

The first transistor T1a may be connected between the second node N2 and a third node N3. The first transistor T1a may include a first electrode E11a connected to the third node N3, a second electrode E12a connected to the second node N2, a first gate electrode E13a connected to the first node N1, and a second gate electrode E14a connected to the second node N2. The first gate electrode E13a may be referred to as a gate electrode, and the second gate electrode E14a may be referred to as a back gate electrode. The first electrode E11a of the first transistor T1a may be electrically connected to the first driving voltage line VL1 through the fifth transistor T5a. The first transistor T1a illustrated in FIG. 5B may correspond to the first transistor T1 illustrated in FIG. 5A.

The second transistor T2a may be connected between the first data line DL1-1 and the first node N1. The second transistor T2a may include a first electrode E21a connected to the first data line DL1-1, a second electrode E22a connected to the first node N1, and a gate electrode E23a connected to the scan line GWL1. The second transistor T2a may be turned on by the scan signal GW1 which is received through the scan line GWL1 to transmit the data signal D1 which is received through the first data line DL1-1 to the first node N1. The second transistor T2a illustrated in FIG. 5B may correspond to the second transistor T2 illustrated in FIG. 5A.

The third transistor T3a may be connected between the third driving voltage line VL3 and a fourth node N4. The third transistor T3a may include a first electrode E31a connected to the third driving voltage line VL3, a second electrode E32a connected to the fourth node N4, and a gate electrode E33a connected to the scan line GIL1. The third transistor T3a may transmit the initializing voltage VINT which is received through the third driving voltage line VL3 to the fourth node N4 in response to the scan signal GI1 received through the scan line GIL1. The third transistor T3a illustrated in FIG. 5B may correspond to the third transistor T3 illustrated in FIG. 5A.

The fourth transistor T4a may be connected between the fourth driving voltage line VL4 and the first node N1. The fourth transistor T4a may include a first electrode E41a connected to the fourth driving voltage line VL4, a second electrode E42a connected to the first node N1, and a gate electrode E43a connected to the scan line GRL1. The fourth transistor T4a may be turned on by the scan signal GR1 which is received through the scan line GRL1 to transmit the reference voltage VREF to the first node N1.

The fifth transistor T5a may be connected between the first driving voltage line VL1 and the third node N3. The fifth transistor T5a may include a first electrode E51a connected to the first driving voltage line VL1, a second electrode E52a connected to the first electrode E11a of the first transistor T1a, and a gate electrode E53a connected to the emission control line EML1. The fifth transistor T5a may be turned on by the emission signal EM1 which is received through the emission control line EML1 to electrically connect the first driving voltage line VL1 to the first electrode E11a of the first transistor T1a.

The sixth transistor T6a may be connected between the second node N2 and the fourth node N4. The sixth transistor T6a may include a first electrode E61a connected to the second node N2, a second electrode E62a connected to the fourth node N4, and a gate electrode E63a connected to the emission control line EMBL1. The sixth transistor T6a may be turned on by the emission signal EMB1 which is received through the emission control line EMBL1 to electrically connect the second node N2 to the fourth node N4.

The second capacitor Cholda may be connected between the first driving voltage line VL1 and the back gate electrode E14a of the first transistor T1a. A first hold opposite electrode Ch1u of the second capacitor Cholda may be connected to the first driving voltage line VL1, and a second hold opposite electrode Ch2a of the second capacitor Cholda may be connected to the back gate electrode E14a of the first transistor T1a. According to an embodiment of the disclosure, the second hold opposite electrode Ch2a of the second capacitor Cholda may be electrically connected to the second node N2. The back gate electrode E14a of the first transistor T1a may be electrically connected to the second node N2. The second capacitor Cholda may be omitted. The first transistor T1a might not include the back gate electrode E14a.

The light emitting element EE may include the anode connected to the second electrode E62a of the sixth transistor T6a or the fourth node N4 and the cathode connected to the second driving voltage line VL2.

One scan line GWL1 among the scan lines GIL1, GRL1, and GWL1 electrically connected to the first sub-pixel PXR1a illustrated in FIG. 5B may correspond to the first scan line SL1 electrically connected to the first sub-pixel PXR1 illustrated in FIG. 5A.

Although FIG. 5B illustrates an example schematic diagram of an equivalent circuit of the first sub-pixel PXR1a, equivalent circuits of the second sub-pixel PXR2, the third sub-pixel PXR3, and the fourth sub-pixel PXR4 illustrated in FIG. 4 may have configurations the same as the configuration of the example schematic diagram of the equivalent circuit of the first sub-pixel PXR1a.

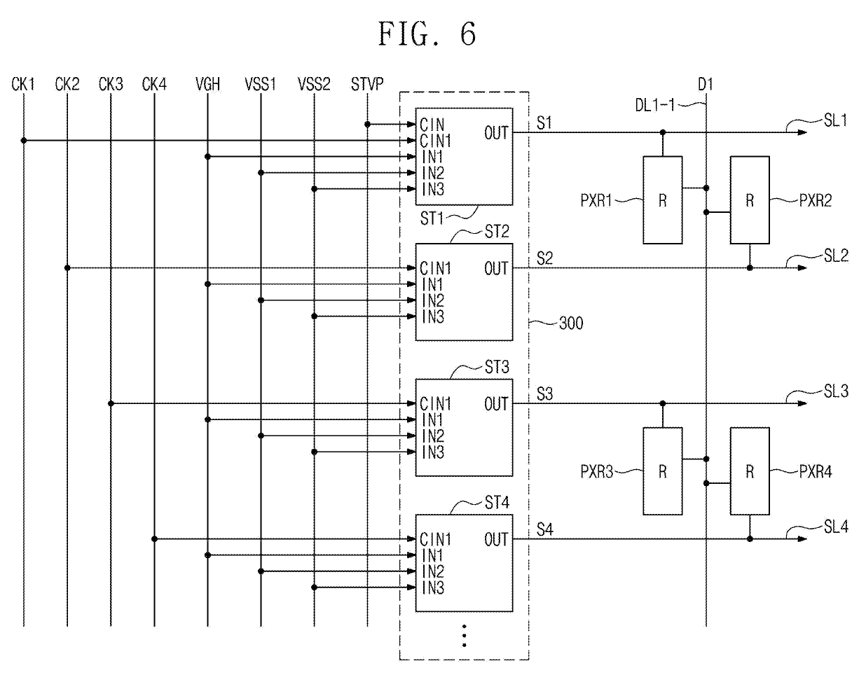

FIG. 6 is a view to describe the scan driving circuit 300 according to an embodiment of the disclosure.

Referring to FIG. 6, the scan driving circuit 300 may include multiple stages ST1, ST2, ST3, and ST4. The stages ST1, ST2, ST3, and ST4 may include the first stage ST1, the second stage ST2, the third stage ST3, and the fourth stage ST4.

The first stage ST1 may include a start control terminal CIN. The start control terminal CIN may receive a start signal STVP. The operations may be sequentially performed from the first stage ST1 in response to the start signal STVP. Each of the first to fourth stages ST1, ST2, ST3, and ST4 may output a carry signal to the next stage, but the disclosure is not necessarily limited thereto.

Each of the first to fourth stages ST1, ST2, ST3, and ST4 may include a clock control terminal CIN1, a first input terminal IN1, a second input terminal IN2, a third input terminal IN3, and an output terminal IN4. The first to fourth stages ST1, ST2, ST3, and ST4 may receive the first to fourth clock signals CK1, CK2, CK3, and CK4, respectively, through the clock control terminal CIN1.

The first to fourth stages ST1, ST2, ST3, and ST4 may receive the high voltage VGH through the first input terminal IN1, the first low voltage VSS1 through the second input terminal IN2, and the second low voltage VSS2 through the third input terminal IN3. A voltage level of the high voltage VGH may be higher than voltage levels of the first low voltage VSS1 and the second low voltage VSS2. The voltage level of the first low voltage VSS1 and the voltage level of the second low voltage VSS2 may be the same as each other or different from each other.

Each of the first to fourth stages ST1, ST2, ST3, and ST4 may output a relevant one of the first to fourth scan signals S1, S2, S3, and S4 to a relevant one of the first to fourth scan lines SL1, SL2, SL3, and SL4 through the output terminal OUT. The first scan line SL1 may transmit the first scan signal S1 which is received from the first stage ST1 to the first sub-pixel PXR1, and the second scan line SL2 may transmit the second scan signal S2 which is received from the second stage ST2 to the second sub-pixel PXR2. The third scan line SL3 may transmit the third scan signal S3 which is received from the third stage ST3 to the third sub-pixel PXR3, and the fourth scan line SL4 may transmit the fourth scan signal S4 which is received from the fourth stage ST4 to the fourth sub-pixel PXR4.

Although four stages ST1, ST2, ST3, and ST4 among stages included in the scan driving circuit 300 have been described with reference to FIG. 6, the above description is applicable to other stages.

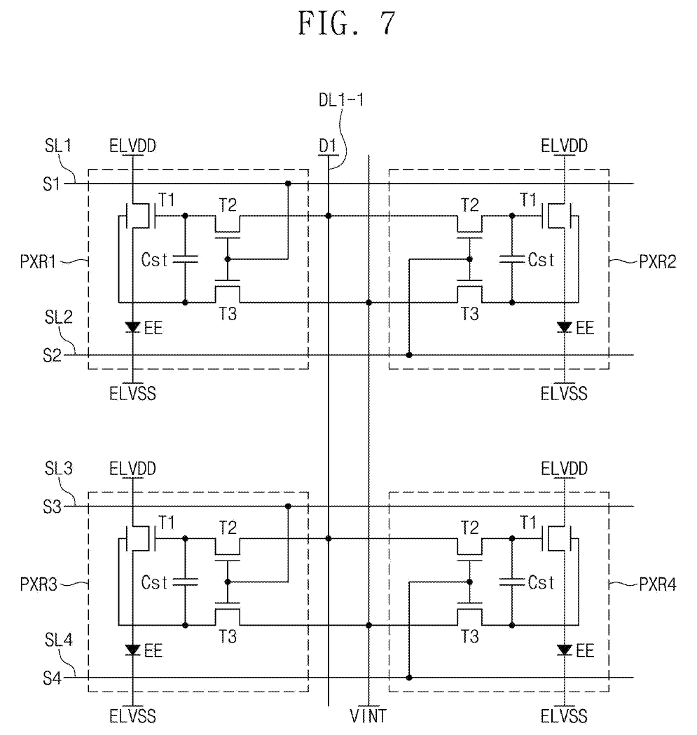

FIG. 7 is an example schematic diagram of an equivalent circuit of the first to fourth sub-pixels PXR1, PXR2, PXR3, and PXR4 according to an embodiment of the disclosure. In FIG. 7, components the same as components illustrated in FIG. 5A will be assigned with the same reference numerals, and the details thereof will be omitted.

Referring to FIG. 7, the first to fourth sub-pixels PXR1, PXR2, PXR3, and PXR4 may be electrically connected to a first data line DL1-1. Accordingly, in a specific driving mode, the first to fourth sub-pixels PXR1, PXR2, PXR3, and PXR4 may receive the same data signal D1 through a first data line DL1-1.

According to an embodiment of the disclosure, the second sub-pixel PXR2 may be spaced apart from the first sub-pixel PXR1 in the first direction DR1, the third sub-pixel PXR3 may be spaced apart from the first sub-pixel PXR1 in the second direction DR2, and the fourth sub-pixel PXR4 may be spaced apart from the third sub-pixel PXR3 in the first direction DR1.

Each of the first to fourth sub-pixels PXR1, PXR2, PXR3, and PXR4 may include the first transistor T1, the second transistor T2, and the third transistor T3.

According to an embodiment of the disclosure, the second transistor T2 of the first sub-pixel PXR1 and the third transistor T3 of the first sub-pixel PXR1 may be controlled in operation by the first scan signal S1, and the second transistor T2 of the second sub-pixel PXR2 and the third transistor T3 of the second sub-pixel PXR2 may be controlled in operation by the second scan signal S2. The second transistor T2 of the third sub-pixel PXR3 and the third transistor T3 of the third sub-pixel PXR3 may be controlled in operation by the third scan signal S3, and the second transistor T2 of the fourth sub-pixel PXR4 and the third transistor T3 of the fourth sub-pixel PXR4 may be controlled in operation by the fourth scan signal S4.

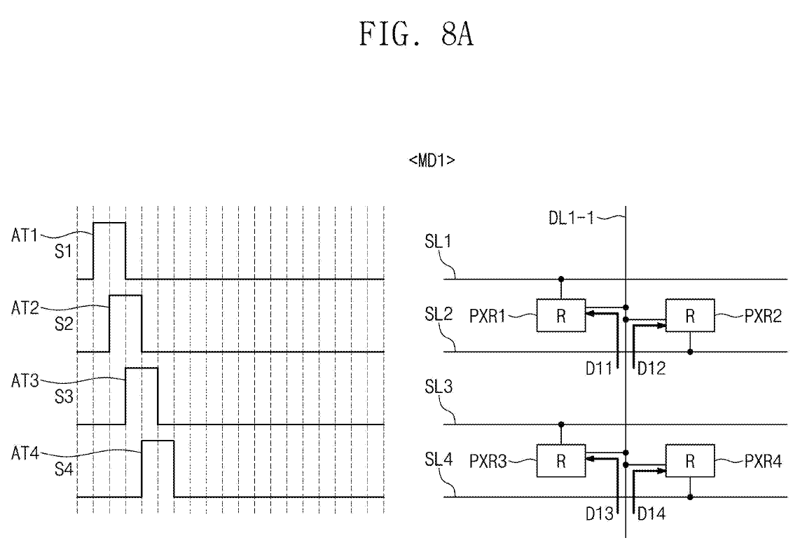

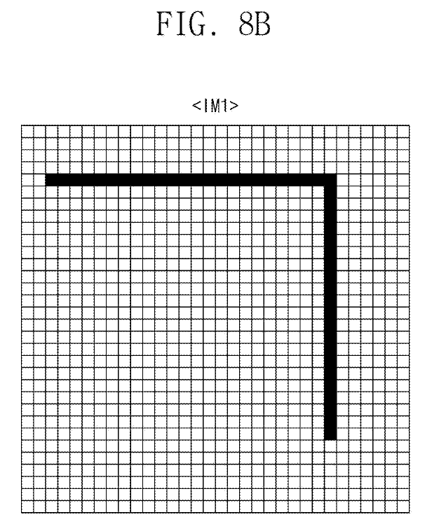

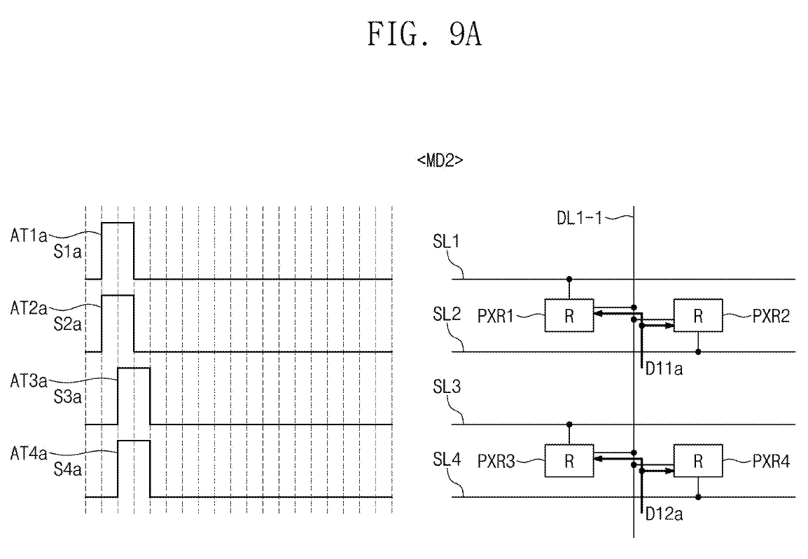

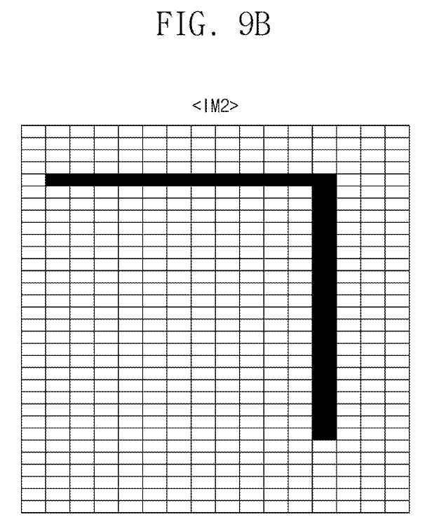

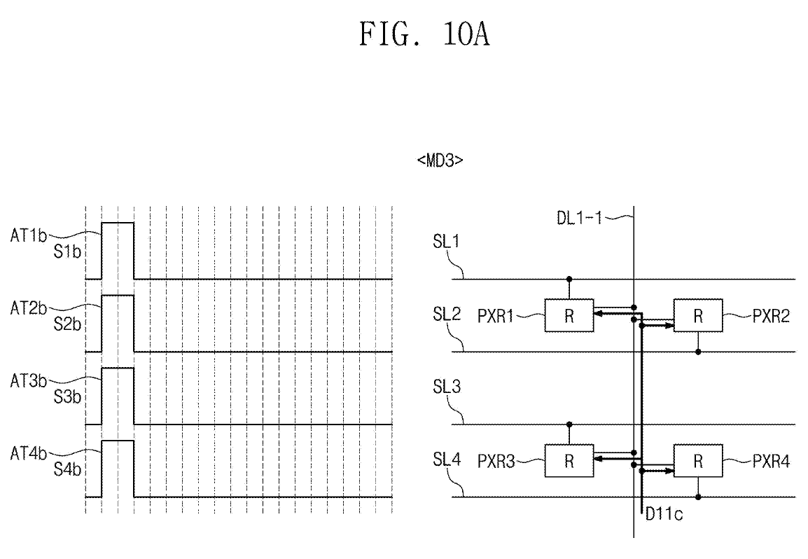

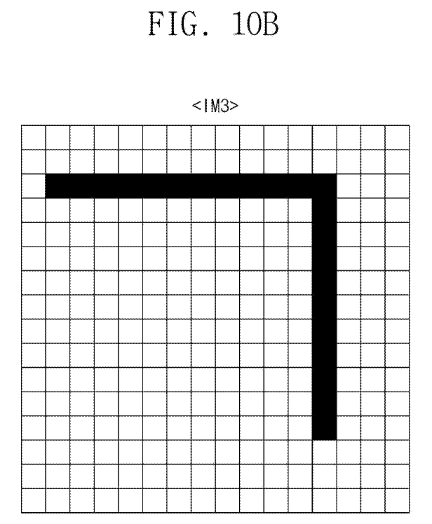

For example, the first to fourth sub-pixels PXR1, PXR2, PXR3, and PXR4 may be driven in multiple operating modes. The operating modes may include a first mode MD1 (see FIG. 8A), a second mode MD2 (see FIG. 9A), and a third mode MD3 (see FIG. 10A). Hereinafter, the first to fourth sub-pixels PXR1, PXR2, PXR3, and PXR4 driven depending on the first mode MD1, the second mode MD2, and the third mode MD3 will be described in detail.

FIG. 8A is a view to describe the first mode MD1 according to an embodiment of the disclosure. FIG. 8B is a view to describe a first image IM1 displayed in the first mode MD1 according to an embodiment of the disclosure.

Referring to FIGS. 7, 8A, and 8B, the first mode MD1 may be an individual driving mode MD1 in which sub-pixels are individually driven. In other words, the first mode MD1 may be a mode in which each of the first to fourth sub-pixels PXR1, PXR2, PXR3, and PXR4 receives a data signal at a different time.

According to an embodiment of the disclosure, in the first mode MD1, a first activation time point AT1 of the first scan signal S1 provided to the first sub-pixel PXR1, a second activation time point AT2 of the second scan signal S2 provided to the second sub-pixel PXR2, a third activation time point AT3 of the third scan signal S3 provided to the third sub-pixel PXR3, and a fourth activation time point AT4 of the fourth scan signal S4 provided to the fourth sub-pixel PXR4 may differ from each other. For example, the first to fourth scan signals S1, S2, S3, and S4 may be sequentially activated in the order of the first scan signal S1, the second scan signal S2, the third scan signal S3, and the fourth scan signal S4.

According to an embodiment of the disclosure, the first to fourth sub-pixels PXR1, PXR2, PXR3, and PXR4 may receive data signals D11, D12, D13, and D14 sequentially provided to the first data line DL1-1. In the first mode MD1, since the first to fourth scan signals S1, S2, S3, and S4 have different activation time points, each of the first to fourth sub-pixels PXR1, PXR2, PXR3, and PXR4 may receive a relevant one among the data signals D11, D12, D13, and D14 to correspond to each different time. For example, the first sub-pixel PXR1 may receive the first data signal D11, the second sub-pixel PXR2 may receive the second data signal D12, the third sub-pixel PXR3 may receive the third data signal D13, and the fourth sub-pixel PXR4 may receive the fourth data signal D14.

According to an embodiment of the disclosure, the first mode MD1 is a mode in which sub-pixels are individually driven one by one. Accordingly, for the first image IM1 displayed in the first mode MD1, a first horizontal resolution in the first direction DR1 may be symmetrical to a first vertical resolution in the second direction DR2. Since the first horizontal resolution and the first vertical resolution are symmetrical to each other, the display quality of the first image IM1 recognized by a user may be improved. Therefore, in the first mode MD1 of the disclosure, the display quality of the electronic device 10 (see FIG. 1) may be improved.

By individually driving each of the same-colored sub-pixels, horizontal and vertical resolution are symmetrical so that motion blur is not sensed by a viewer.

FIG. 9A is a view to describe the second mode MD2 according to an embodiment of the disclosure. FIG. 9B is a view to describe a second image IM2 displayed in the second mode MD2 according to an embodiment of the disclosure.

Referring to FIGS. 7, 9A, and 9B,the second mode MD2 may be a simultaneous driving mode MD2 in which sub-pixels are simultaneously driven. In other words, the second mode MD2 may be a mode in which the first sub-pixel PXR1 and the second sub-pixel PXR2 are simultaneously driven, and the third sub-pixel PXR3 and the fourth sub-pixel PXR4 are simultaneously driven.

According to an embodiment of the disclosure, a first activation time point AT1a of a first scan signal S1a provided to the first sub-pixel PXR1 may be the same as a second activation time point AT2a of a second scan signal S2a provided to the second sub-pixel PXR2. A third activation time point AT3a of a third scan signal S3a provided to the third sub-pixel PXR3 may be the same as a fourth activation time point AT4a of a fourth scan signal S4a provided to the fourth sub-pixel PXR4. The first activation time point AT1a of the first scan signal S1a may differ from the third activation time point AT3a of the third scan signal S3a.

According to an embodiment of the disclosure, in the second mode MD2, the first sub-pixel PXR1 and the second sub-pixel PXR2 may receive a first data signal D11a at the same time. The third sub-pixel PXR3 and the fourth sub-pixel PXR4 may receive a second data signal D12a at the same time. Accordingly, in the second mode MD2, the first sub-pixel PXR1 and the second sub-pixel PXR2 may simultaneously express the same grayscale level (or the same image), and the third sub-pixel PXR3 and the fourth sub-pixel PXR4 may simultaneously express the same grayscale level.

According to an embodiment of the disclosure, since the second mode MD2 is a mode in which two sub-pixels are simultaneously driven, a frame rate (or frames per second) may increase in the second mode MD2, as compared to the first mode MD1 in which sub-pixels are individually driven one by one. In other words, the second frame rate in the second mode MD2 may be higher than the first frame rate in the first mode MD1. According to an embodiment, the second frame rate may be two times the first frame rate. Since the second frame rate increases in the second mode MD2 which is the simultaneous driving mode MD2 even if the horizontal resolution of the second image IM2 displayed in the second mode MD2 decreases, motion blur of the image would not be recognized by the user. Accordingly, the display quality of the electronic device 10 (see FIG. 1) may be improved.

By driving more than one sub-pixel of a same color at a same time, sub-pixels may be driven simultaneously. However frame rate in the second mode is higher than in the first mode so that the horizontal and the vertical resolutions are symmetrical so that the viewer does not sense motion blur.

FIG. 10A is a view to describe the third mode MD3 according to an embodiment of the disclosure. FIG. 10B is a view to describe a third image IM3 displayed in the third mode MD3 according to an embodiment of the disclosure.

Referring to FIGS. 7, 10A, and 10B, the third mode MD3 may be a simultaneous driving mode MD3 in which four sub-pixels are simultaneously driven. In other words, the third mode MD3 may be a mode in which all of the first sub-pixel PXR1, the second sub-pixel PXR2, the third sub-pixel PXR3, and the fourth sub-pixel PXR4 are simultaneously driven.

According to an embodiment of the disclosure, in the third mode MD3, a first activation time point AT1b of a first scan signal S1b provided to the first sub-pixel PXR1, a second activation time point AT2b of a second scan signal S2b provided to the second sub-pixel PXR2, a third activation time point AT3b of a third scan signal S3b provided to the third sub-pixel PXR3, and a fourth activation time point AT4b of a fourth scan signal S4b provided to the fourth sub-pixel PXR4 may be the same.

According to an embodiment of the disclosure, in the third mode MD3, the first to fourth sub-pixels PXR1, PXR2, PXR3, and PXR4 may receive a first data signal D11c at the same time. For example, the first to fourth sub-pixels PXR1, PXR2, PXR3, and PXR4 may simultaneously express the same grayscale level.

According to an embodiment of the disclosure, since the third mode MD3 is a mode in which the four sub-pixels are simultaneously driven, the frame rate may increase in the third mode MD3, as compared to the first mode MD1 illustrated in FIG. 8A and the second mode MD2 illustrated in FIG. 9A. In other words, the third frame rate in the third mode MD3 may be higher than each of the first frame rate in the first mode MD1 and the second frame rate in the second mode MD2. According to an embodiment, the second frame rate may be two times the first frame rate, and the third frame rate may be four times the first frame rate.

In case that the sub-pixels adjacent to each other in the first direction DR1 increase the frame rate by four times without sharing a data line which differs from an embodiment of the disclosure, the difference between the horizontal resolution in the first direction DR1 and the vertical resolution in the second direction DR2 may be quadrupled. This is because asymmetrical resolutions cause image quality degradation. However, according to an embodiment of the disclosure, the first to fourth sub-pixels PXR1, PXR2, PXR3, and PXR4 connected to the four scan lines and one (e.g., a single) data line may be arranged in two rows and two columns. Accordingly, the first to fourth sub-pixels PXR1, PXR2, PXR3, and PXR4 are simultaneously driven in the third mode MD3 showing the frame rate quadrupled and a second horizontal resolution in the first direction DR1 and a second vertical resolution in the second direction DR2 may be symmetrical to each other in the third image IM3 displayed in the third mode MD3. Accordingly, even if the second horizontal resolution and the second vertical resolution of the third image IM3 decrease, as compared to the first image IM1 illustrated in FIG. 8B, the second horizontal resolution and the second vertical resolution of the third image IM3 are symmetrical to each other, thereby preventing the image quality of the electronic device 10 (see FIG. 1) from being degraded which is recognized by the user when the resolutions asymmetrically decrease. Since the third frame rate increases in the third mode MD3 which is the simultaneous driving mode MD3, the motion blur that would otherwise be recognized by the user may be prevented. Accordingly, the display quality of the electronic device 10 (see FIG. 1) may be improved.

As described above, each of the first to fourth sub-pixels may be electrically connected to one (e.g., a single) data line and may be driven in the operating modes. The operating modes may include the individual driving mode and the simultaneous driving mode. The frame rate may increase in the simultaneous driving mode, thereby preventing the motion blur of the image that would otherwise be recognized by the user. The horizontal resolution and the vertical resolution of the image may be symmetrical to each other in the simultaneous driving mode. Accordingly, the display quality of the electronic device may be improved.

Although an embodiment of the disclosure has been described for illustrative purposes, those skilled in the art will appreciate that various modifications, and substitutions are possible, without departing from the scope and spirit of the disclosure as disclosed in the accompanying claims. Accordingly, the technical scope of the disclosure is not necessarily limited to the detailed description of this specification, but should be defined by the claims.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. A display device comprising:
a first sub-pixel;
a second sub-pixel spaced apart from the first sub-pixel in a first direction and emitting light of substantially the same color as the first sub-pixel;
a first scan line extending in the first direction, electrically connected to the first sub-pixel, and transmitting a first scan signal to the first sub-pixel;
a second scan line extending in the first direction, electrically connected to the second sub-pixel, and transmitting a second scan signal to the second sub-pixel; and
a data line extending in a second direction intersecting the first direction and electrically connected to the first sub-pixel and the second sub-pixel.

2. The display device of claim 1, wherein
the first sub-pixel and the second sub-pixel are driven in a plurality of operating modes, and
the plurality of operating modes include a first mode and a second mode having mutually different frame rates.

3. The display device of claim 2, wherein in the first mode, a first activation time point of the first scan signal differs from a second activation time point of the second scan signal.

4. The display device of claim 2, wherein in the second mode, a first activation time point of the first scan signal is the same as a second activation time point of the second scan signal.

5. The display device of claim 2, wherein a second frame rate in the second mode is two times a first frame rate in the first mode.

6. The display device of claim 1, wherein
each of the first sub-pixel and the second sub-pixel includes a first transistor, a second transistor, and a third transistor,
the second transistor of the first sub-pixel and the third transistor of the first sub-pixel are controlled in operation by the first scan signal, and
the second transistor of the second sub-pixel and the third transistor of the second sub-pixel are controlled in operation by the second scan signal.

7. The display device of claim 1, further comprising:
a third sub-pixel spaced apart from the first sub-pixel in the second direction intersecting the first direction;
a fourth sub-pixel spaced apart from the third sub-pixel in the first direction;
a third scan line extending in the first direction, electrically connected to the third sub-pixel, and transmitting a third scan signal to the third sub-pixel; and
a fourth scan line extending in the first direction, electrically connected to the fourth sub-pixel, and transmitting a fourth scan signal to the fourth sub-pixel,
wherein the first sub-pixel, the second sub-pixel, the third sub-pixel, and the fourth sub-pixel emit light of substantially the same color.

8. The display device of claim 7, wherein
the first sub-pixel, the second sub-pixel, the third sub-pixel, and the fourth sub-pixel are driven in a plurality of operating modes, and
the plurality of operating modes include a first mode, a second mode, and a third mode having mutually different frame rates.

9. The display device of claim 8, wherein in the first mode, a first activation time point of the first scan signal, a second activation time point of the second scan signal, a third activation time point of the third scan signal, and a fourth activation time point of the fourth scan signal differ from each other.

10. The display device of claim 8, wherein
a first activation time point of the first scan signal is the same as a second activation time point of the second scan signal,
a third activation time point of the third scan signal is the same as a fourth activation time point of the fourth scan signal, and
the first activation time point differs from the third activation time point, in the second mode.

11. The display device of claim 8, wherein in the third mode, a first activation time point of the first scan signal, a second activation time point of the second scan signal, a third activation time point of the third scan signal, and a fourth activation time point of the fourth scan signal are the same.

12. The display device of claim 8, wherein
a second frame rate in the second mode is two times a first frame rate in the first mode, and
a third frame rate in the third mode is four times the first frame rate in the first mode.

13. The display device of claim 8, wherein
in the first mode, a first horizontal resolution in the first direction is symmetrical to a first vertical resolution in the second direction, and
in the third mode, a second horizontal resolution in the first direction is symmetrical to a second vertical resolution in the second direction.

14. The display device of claim 7, wherein
each of the first sub-pixel, the second sub-pixel, the third sub-pixel, and the fourth sub-pixel includes a first transistor, a second transistor, and a third transistor,
the second transistor of the first sub-pixel and the third transistor of the first sub-pixel are controlled in operation by the first scan signal,
the second transistor of the second sub-pixel and the third transistor of the second sub-pixel are controlled in operation by the second scan signal,
the second transistor of the third sub-pixel and the third transistor of the third sub-pixel are controlled in operation by the third scan signal, and
the second transistor of the fourth sub-pixel and the third transistor of the fourth sub-pixel are controlled in operation by the fourth scan signal.

15. A display device comprising:
a first pixel group including a first sub-pixel;
a second pixel group spaced apart from the first pixel group in a first direction and including a second sub-pixel;
a third pixel group spaced apart from the first pixel group in a second direction intersecting the first direction and including a third sub-pixel;
a fourth pixel group spaced apart from the third pixel group in the first direction and including a fourth sub-pixel;
a data line extending in the second direction, and electrically connected to the first sub-pixel, the second sub-pixel, the third sub-pixel, and the fourth sub-pixel;
a first scan line extending in the first direction, electrically connected to the first sub-pixel, and transmitting a first scan signal to the first sub-pixel;
a second scan line extending in the first direction, electrically connected to the second sub-pixel, and transmitting a second scan signal to the second sub-pixel;
a third scan line extending in the first direction, electrically connected to the third sub-pixel, and transmitting a third scan signal to the third sub-pixel; and
a fourth scan line extending in the first direction, electrically connected to the fourth sub-pixel, and transmitting a fourth scan signal to the fourth sub-pixel,
wherein the first sub-pixel, the second sub-pixel, the third sub-pixel, and the fourth sub-pixel emit light of substantially the same color.

16. The display device of claim 15, wherein
the first sub-pixel, the second sub-pixel, the third sub-pixel, and the fourth sub-pixel are driven in a plurality of operating modes, and
the plurality of operating modes include a first mode, a second mode, and a third mode.

17. The display device of claim 16, wherein
in the first mode, a first activation time point of the first scan signal, a second activation time point of the second scan signal, a third activation time point of the third scan signal, and a fourth activation time point of the fourth scan signal differ from each other,
in the second mode, the first activation time point is the same as the second activation time point, the third activation time point is the same as the fourth activation time point, and the first activation time point differs from the third activation time point, and
in the third mode, the first activation time point, the second activation time point, the third activation time point, and the fourth activation time point are the same.

18. The display device of claim 16, wherein
a second frame rate in the second mode is two times a first frame rate in the first mode, and
a third frame rate in the third mode is four times the first frame rate in the first mode.

19. The display device of claim 16, wherein
in the first mode, a first horizontal resolution in the first direction is symmetrical to a first vertical resolution in the second direction, and
in the third mode, a second horizontal resolution in the first direction is symmetrical to a second vertical resolution in the second direction.

20. An electronic device comprising:
a display device; and
a processor configured to control an operation of the display device,
wherein the display device includes:
a display panel including a plurality of sub-pixels disposed in a first direction and a second direction intersecting the first direction, a plurality of scan lines electrically connected to the plurality of sub-pixels, and a plurality of data lines electrically connected to the plurality of sub-pixels; and
a data driving circuit configured to output a plurality of data signals to the plurality of data lines, wherein
the plurality of sub-pixels include a first sub-pixel, a second sub-pixel spaced apart from the first sub-pixel in the first direction, a third sub-pixel spaced apart from the first sub-pixel in the second direction, and a fourth sub-pixel spaced apart from the third sub-pixel in the first direction,
the plurality of scan lines include a first scan line electrically connected to the first sub-pixel, a second scan line electrically connected to the second sub-pixel, a third scan line electrically connected to the third sub-pixel, and a fourth scan line electrically connected to the fourth sub-pixel,
the plurality of data lines include a data line electrically connected to each of the first sub-pixel, the second sub-pixel, the third sub-pixel, and the fourth sub-pixel, and
the first sub-pixel, the second sub-pixel, the third sub-pixel, and the fourth sub-pixel emit light of substantially the same color.
